(19) United States
(12) Patent Application Publication
(10) Pub. No.: US 2025/0150061 A1
(43) Pub. Date: May 8, 2025

(54) ELECTRONIC DEVICE

(71) Applicant: Innolux Corporation, Miaoli County (TW)

(72) Inventor: Yan-Zheng Wu, Miaoli County (TW)

(73) Assignee: Innolux Corporation, Miaoli County (TW)

(21) Appl. No.: 18/902,949

(22) Filed: Oct. 1, 2024

Related U.S. Application Data
(60) Provisional application No. 63/595,339, filed on Nov. 2, 2023.

(30) Foreign Application Priority Data
Jun. 19, 2024 (CN) 202410795227.3

(51) Int. Cl. H03J 3/18; H05K 1/02

(52) U.S. Cl. CPC H03J 3/185; H05K 1/0242; H05K 1/025; H03J 2200/36

(57) ABSTRACT

Disclosed is an electronic device including a substrate, a radio frequency (RF) modulation element, a control circuit and a radio frequency (RF) choke. The RF modulation element, the control circuit and the RF choke are disposed on the substrate. The RF choke is electrically coupled between the RF modulation element and the control circuit. The orthographic projections of the RF modulation element, the control circuits and the RF choke on the substrate do not overlap each other.

### CROSS-REFERENCE TO RELATED APPLICATION

This application claims the priority benefit of U.S. provisional application Ser. No. 63/595,339, filed on Nov. 2, 2023, and China application serial no. 202410795227.3, filed on Jun. 19, 2024. The entirety of the above-mentioned patent application is hereby incorporated by reference herein and made a part of this specification.

### BACKGROUND

### Field of the Disclosure

The present disclosure relates to an electronic device, and in particular, to an electronic device that may modulate phase and amplitude of high-frequency electromagnetic waves.

### Description of Related Art

Diode-tuned RF (radio frequency) signal modulation array makes diode to change the resonant phase and amplitude of each element through different DC signals. In this way, it is possible to generate required phase and amplitude modes on the entire RF signal modulation plane, so as to adjust the emission angle of the output RF signal. However, since DC signals are required for the diode element to change the resonant phase and amplitude of high-frequency electromagnetic waves, it is necessary to make room inside the diode element to set a circuit design that isolates the DC bias voltage from RF electromagnetic signals; as a result, diode elements are large in size and the unit price thereof is high.

### SUMMARY OF THE DISCLOSURE

The present disclosure is related to an electronic device with lower cost.

According to an embodiment of the disclosure, an electronic device includes a substrate, a radio frequency (RF) modulation element, a control circuit and a radio frequency (RF) choke. The RF modulation element, the control circuit and the RF choke are disposed on the substrate. The RF choke is electrically coupled between the RF modulation element and the control circuit. The orthographic projections of the RF modulation element, the control circuit and the RF choke on the substrate do not overlap each other.

Based on the above, in the electronic device of the present disclosure, since the orthographic projections of the RF modulation element, the control circuit and the RF choke on the substrate do not overlap each other, that is, the RF choke is not integrated into the RF modulation element, compared with the related art in which the circuit design for isolating RF electromagnetic signals is integrated in the RF modulation element, the RF modulation element of the present disclosure may have a smaller size, thereby effectively reducing the cost of the electronic device of the present disclosure.

### BRIEF DESCRIPTION OF THE DRAWINGS

The accompanying drawings are incorporated to provide a further understanding of the present disclosure, and are incorporated in and constitute a part of this specification. The drawings illustrate embodiments of the disclosure and, together with the description, serve to explain principles of the disclosure.

FIG. 1 is a schematic view of an electronic device according to an embodiment of the present disclosure.

FIG. 2 is a partial enlarged schematic view of the electronic device of FIG. 1.

FIG. 3 is a schematic view of an electronic device according to another embodiment of the present disclosure.

FIG. 4 is a schematic cross-sectional view along line A-A′ of FIG. 3.

FIG. 5 is a schematic view of an electronic device according to another embodiment of the present disclosure.

FIG. 6 is a schematic cross-sectional view along line B-B′ of FIG. 5.

FIG. 7 is a partial enlarged schematic view of the electronic device of FIG. 5.

FIG. 8 to FIG. 10 are schematic views of various electronic devices according to various embodiments of the present disclosure.

### DESCRIPTION OF EMBODIMENTS

This disclosure may be understood by referring to the following detailed description in conjunction with the accompanying drawings. It should be noted that, in order to facilitate understanding and for the concision of the drawings, only a part of the electronic device is shown in the drawings in this disclosure, and the specific elements in the drawings are not drawn according to actual scale. In addition, the number and size of each element in the figure are only exemplary and are not used to limit the scope of the disclosure.

In the description of the disclosure and the appended claims, certain terms will be used to refer to specific elements. Persons skilled in the art would understand that electronic device manufacturers may refer to the same elements under different names.

This disclosure does not intend to distinguish between elements that have the same functions but different names.

In the following description and claims, the words “having” and “including” are open-ended words and thus should be interpreted as meaning “including but not limited to.”

In addition, relative terms, such as “below” or “bottom” and “above” or “top,” may be used in the embodiments to describe the relative relationship of one element to another element of the drawings. It will be understandable that if the device in the drawings is turned upside down, elements described on the “lower” side will become elements described on the “upper” side.

In some embodiments of the disclosure, regarding the words such as “connect”, “interconnected”, etc. referring to bonding and connection, unless specifically defined, these words mean that two structures are in direct contact or two structures are not in direct (indirect) contact, and other structures are provided to be disposed between the two structures. The word for joining and connecting may also include the case where both structures are movable or both structures are fixed. Furthermore, the term “coupling” includes transfer of energy between two structures by means of direct or indirect electrical connection, or transfer of energy between two separate structures by means of mutual induction.

It should be understood that when an element or film layer is referred to as being “on”, or “connected to” another element or film layer, the element or film layer may be directly on or connected to the another element or film layer, or intervening elements or film layers may also be present in between (non-direct circumstances). In contrast, when an element is referred to as being “directly on” or “directly connected to” another element or film layer, no intervening elements or film layers are present in between.

The term “about”, “equal to”, “equivalent” or “same”, “substantially”, or “essentially” is typically interpreted so that a value is within 20% of a given value or range, or within 10%, 5%, 3%, 2%, 1%, or 0.5% of a given value or range.

As used herein, the term(s) “film” and/or “layer” may refer to any continuous or discontinuous structure and material (e.g., materials deposited by the methods disclosed herein). For example, films and/or layers may include two-dimensional materials, three-dimensional materials, nanoparticles, or even partial or complete molecular layers, or partial or complete atomic layers, or atomic and/or molecular clusters. The films or layers may include materials or layers having pinholes and may be at least partially continuous.

Although the terms first, second, third, and so on may be used to describe diverse constituent elements, such constituent elements are not limited by the terms. The terms are only used to distinguish one single element from other element in the specification. The same terms may not be used in the claims, and may be replaced with “first,” “second,” “third” and the like in the order in which the elements in the claims are declared.

Accordingly, a first element in the following description may be a second element in the claims.

Unless otherwise defined, all terms (including technical and scientific terms) used herein have the same meaning as commonly understood by one of ordinary skill in the art. It is understandable that these terms, such as those defined in commonly used dictionaries, should be interpreted to have a meaning consistent with the background or context of the related art and the disclosure, and not interpreted in an idealized or overly formal manner, unless specifically defined herein.

It should be understood that the following embodiments may replace, reorganize, and mix the technical features in several different embodiments to complete other embodiments without departing from the spirit of the disclosure.

The electronic device of the disclosure may include a display device, an antenna device, a sensing device, a light-emitting device, or a splicing device, but not limited thereto. The electronic device may include a bendable or flexible electronic device. The electronic device may include an electronic element. The electronic element may include a passive element, an active element, or a combination thereof, for example, a capacitor, a resistor, an inductor, a varactor, a filter, a diode, a transistor, a sensor, MEMS, a liquid crystal chip, etc., but not limited thereto. The diode may include a light-emitting diode (LED) or a non-light-emitting diode. The diodes include P-N junction diode, PIN diode or constant current diode. The light-emitting diode may include, for example, an organic light-emitting diode (OLED), a mini LED, a micro LED, a quantum dot LED, fluorescence, phosphor, other suitable materials, or a combination of the above, but not limited thereto. The sensor may include, for example, a capacitive sensor, an optical sensor, an electromagnetic sensor, a fingerprint sensor (FPS), a touch sensor, an antenna, or a pen sensor, etc., but not limited thereto. Hereinafter, the display device will be used as an electronic device to illustrate the content of the disclosure, but the disclosure is not limited thereto.

Reference will now be made in detail to the exemplary embodiments of the disclosure, and examples of the exemplary embodiments are illustrated in the accompanying drawings. Whenever possible, the same reference symbols are used in the drawings and descriptions to indicate the same or similar parts.

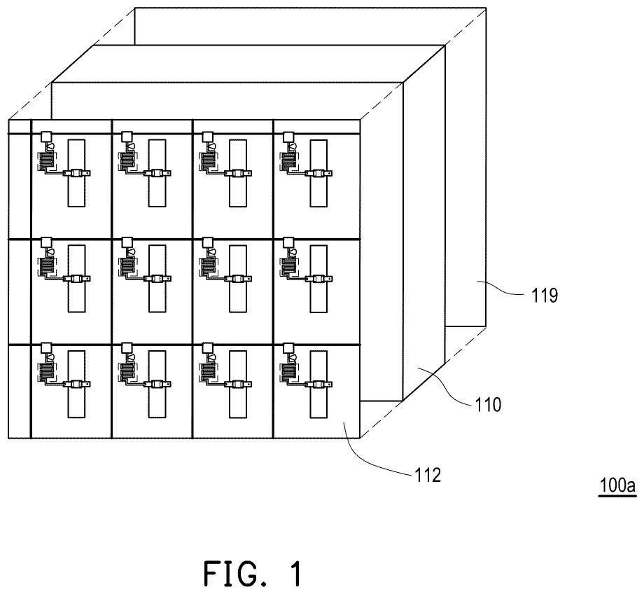

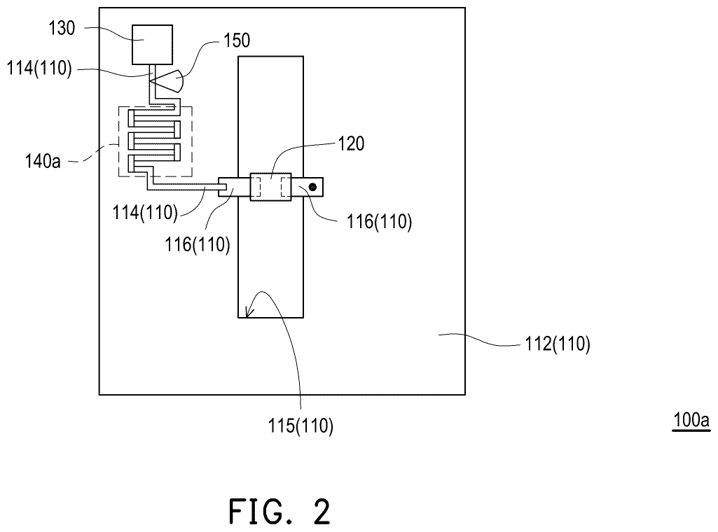

FIG. 1 is a schematic view of an electronic device according to an embodiment of the present disclosure. FIG. 2 is a partial enlarged schematic view of the electronic device of FIG. 1. Please refer to FIG. 1 and FIG. 2 at the same time. The electronic device 100a includes a substrate 110, a radio frequency (RF) modulation element 120, a control circuit 130 and a radio frequency (RF) choke 140a. The RF modulation element 120, the control circuit 130 and the RF choke 140a are disposed on the substrate 110. The RF choke 140a is electrically coupled between the RF modulation element 120 and the control circuit 130. The orthographic projections of the RF modulation element 120, the control circuit 130 and the RF choke 140a on the substrate 110 do not overlap each other. That is to say, the RF choke 140a is not integrated in the RF modulation element 120.

Specifically, in this embodiment, the substrate 110 includes a metal layer 112 and an opening 115 penetrating the metal layer 112. The orthographic projection of the RF modulation element 120 on the substrate 110 overlaps the opening 115, and the orthographic projections of the control circuit 130 and the RF choke 140a on the substrate 110 overlap the metal layer 112. Furthermore, the substrate 110 of this embodiment also includes a signal trace 114 disposed above the metal layer 112, wherein the signal trace 114 is connected between the RF modulation element 120 and the RF choke 140a and connected between the RF choke 140a and the control circuit 130. In an embodiment, a reflective structural layer 119 may also be disposed on the other side surface of the substrate 110, wherein the metal layer 112 and the reflective structural layer 119 are respectively located on opposite side surfaces of the substrate 110. In an embodiment, the reflective structural layer 119 may be a metal layer or a metal sheet over the entire surface of another substrate. It should be noted that the reflective structural layer 119 and the substrate 110 do not need to be closely attached, and may be a cavity or filled with low-loss material. In addition, the metal layer 112 and the reflective structural layer 119 are provided mainly to form a space for high-frequency signal transmission.

In an embodiment, the substrate 110 may be, for example, a rigid substrate, a flexible substrate, or a combination of the foregoing. For example, the material of the substrate 110 may be glass, quartz, silicon wafer, sapphire, Group III-V semiconductor material, ceramic, polycarbonate (PC), polyimide (PI), polyethylene terephthalate (PET), other suitable substrate materials, or combinations of the foregoing, but are not limited thereto. In an embodiment, the substrate 110 may also be a printed circuit board. In an embodiment, the metal layer 112 may resonate with the received electromagnetic wave signal (or optical signal), and the material of the metal layer 112 may be, for example, copper, aluminum, silver, gold, indium tin oxide (ITO), metal alloys, other suitable conductive materials or combinations of the aforementioned materials, but are not limited thereto. In an embodiment, the signal trace 114 is, for example, a DC signal trace, and the material of the signal trace 114 is, for example, metal.

Parameters related to the RF modulation element 120 may be modulated by signals applied to the RF modulation element 120. Relevant parameters may include dielectric constant, area, depletion region width of semiconductor, height of metal plate, etc., but are not limited thereto. In an embodiment, the RF modulation element 120 may be packaged by using a Panel Level Package (PLP), a Wafer Level Package (WLP) or a Fan-Out Wafer Level Package (FOWLP) and other technologies that are used to package modulation elements. In an embodiment, the RF modulation element 120 may be bonded to the corresponding one or more conductive patterns 116 and/or signal trace 114 in the substrate 110 through direct bonding, micro-bonding or flip-chip bonding. In an embodiment, the RF modulation element 120 may be a chip integrating active elements, passive elements, or a combination of the above, such as a capacitor, a resistor, an inductor, a diode, a transistor, a micro-electromechanical system, or a combination of the above. The RF modulation element 120 may be bonded to the substrate 110 having redistribution signal lines or conductive patterns 116 through direct bonding, micro-bonding or flip-chip bonding.

In an embodiment, the RF modulation element 120 may be used to modulate RF waves or electromagnetic waves. For example, the RF modulation element 120 may include a capacitive element, such as a varactor, that is, the capacitance of the RF modulation element 120 may be variable, but is not limited thereto. The varactor may be formed by a liquid crystal device, a varactor diode or a micro electro mechanical system (MEMS), but is not limited thereto. By changing the voltage applied to the RF modulation element 120 through the metal layer 112 and the signal trace 114, it is possible to control the equivalent capacitance of the RF modulation element 120, causing the phase and amplitude of the electromagnetic wave to change correspondingly, and thus controlling the direction of electromagnetic waves or improve the directivity of the electronic device 100a.

In an embodiment, the control circuit 130 is, for example, a switching element, such as a transistor or an integrated circuit. The type of transistor is not limited in the disclosure. For example, the transistor may include a bipolar junction transistor (BJT), a field effect transistor (FET), a metal oxide semiconductor field effect transistor (MOSFET), a thin-film transistor (TFT), a high electron mobility transistor (HEMT), a junction gate field effect transistor (JFET), an insulated gate bipolar transistor (IGBT), a nano field effect transistor (nano FET), an ion sensitive field effect transistor (ISFET), a tunnel field effect transistor (TFET), an organic field-effect transistor (OFET) or a combination of the above, but the disclosure is not limited thereto.

In order to prevent the DC signal from being interfered by the RF signal, an RF choke 140a is disposed on the connection path between the RF modulation element 120 and the control circuit 130, thereby isolating RF electromagnetic waves. In short, the RF choke 140a used to isolate RF electromagnetic signals may be regarded as an isolation circuit design. In an embodiment, the RF choke 140a is, for example, an inductor, but is not limited thereto.

It should be noted that the normal operation of the RF modulation element 120 (such as a diode) requires consideration of two key issues: maintaining a stable DC signal and preventing RF signal leakage. DC signal lines designed with high resistance or/and high inductance may block RF signal leakage. High-impedance DC signal lines may adopt metals with relatively low conductivity (such as ITO, IZO, IGZO, etc.) or/and metal thickness lower than the skin depth of the lowest operating frequency of the RF signal. DC signal lines may be wired to form a two-dimensional (planar, e.g., mosquito coil-shaped) inductor or a three-dimensional (three-dimensional, e.g., spring-shaped) inductor to achieve high inductance design. The inductor is formed by winding conductive wires into multiple turns, and the greater the number of turns, the greater the effect of the inductance.

In addition, in order to stabilize the supply of DC voltage, the electronic device 100a of this example further includes a bypass capacitor 150, which is electrically coupled between the control circuit 130 and the RF choke 140a.

In an embodiment, an RF modulation element 120, a control circuit 130, an RF choke 140a and a bypass capacitor 150 may be regarded as a modulation unit, and multiple modulation units may be disposed on the substrate 110. These modulation units may be arranged in an array, and when the RF modulation element 120 is a diode, the electronic device 100a may be regarded as a diode-tuned RF signal modulation array, but the disclosure is not limited thereto.

In short, in the electronic device 100a of this embodiment, since the orthographic projections of the RF modulation element 120, the control circuit 130 and the RF choke 140a on the substrate 110 do not overlap each other, that is, the RF choke 140a that prevents DC signals from being interfered by RF signals is not integrated in the RF modulation element 120, but is separately disposed on the substrate 110, compared with the related art in which the circuit design for isolating RF electromagnetic signals is integrated in the RF modulation element, the RF modulation element 120 of the present disclosure may have a smaller size, thereby effectively reducing the cost of the electronic device 100a of the present embodiment.

It should be noted here that the following embodiments adopt the component numbers and part of the contents of the previous embodiments, wherein the same numbers are used to represent the same or similar components, and descriptions of the same technical contents are omitted. For descriptions of omitted parts, reference may be made to the foregoing embodiments and will not be repeated in the following embodiments.

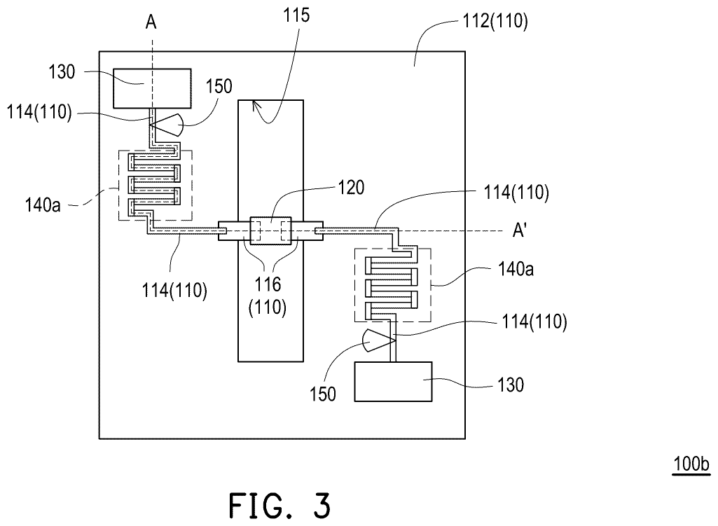

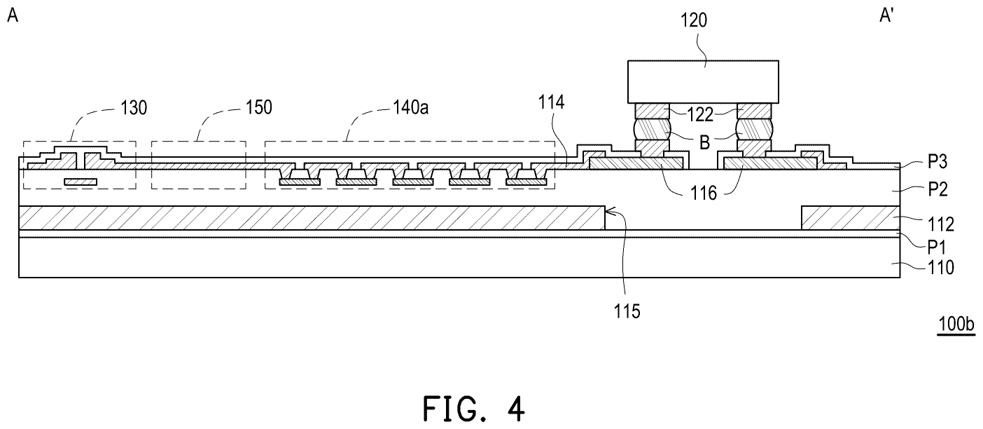

FIG. 3 is a schematic view of an electronic device according to another embodiment of the present disclosure. FIG. 4 is a schematic cross-sectional view along line A-A′ of FIG. 3. For convenience of explanation, some components, such as the protective layer, are omitted from FIG. 3. Please refer to FIG. 2, FIG. 3 and FIG. 4 at the same time. The electronic device 100b is similar to the electronic device 100a of FIG. 1 and FIG. 2, and the difference between the two is that the electronic device 100b of the present embodiment includes a RF modulation element 120, two control circuits 130, two RF chokes 140a and two bypass capacitors 150, wherein the pads 122 of the RF modulation element 120 may be electrically and physically connected to the conductive pattern 116 of the substrate 110 through the solder B. Two control circuits 130, two RF chokes 140a and two bypass capacitors 150 are respectively disposed on both sides of the RF modulation element 120 and arranged diagonally, and are connected through signal traces 114. In particular, in this embodiment, the bypass capacitor 150, the RF choke 140a and the signal trace 114 are integrated together. That is to say, the conductive lines and/or conductive patterns of part of the bypass capacitor 150 and part of the RF choke 140a and the signal trace 114 belong to the same film layer. In an embodiment, there may be only one control circuit 130, that is, only the control circuit 130 in the upper left corner of FIG. 3, which still falls within the scope to be protected by the present disclosure.

In addition, the substrate 110 of this embodiment further includes protective layers P1, P2, and P3. The protective layer P1 is disposed between the substrate 110 and the metal layer 112, and the opening 115 exposes part of the protective layer P1. The protective layer P2 is disposed on the metal layer 112 and covers the metal layer 112 and the inner wall of the opening 115. The protective layer P2 may have a large thickness, so the protective layer P2 may be regarded as a flat layer. The protective layer P3 is disposed on the protective layer P2 and covers part of the conductive pattern 116 and the signal trace 114, wherein the protective layer P3 may be regarded as a solder mask layer. It should be noted that this embodiment does not limit the number of protective layers, and may be divided into multiple layers according to requirements of process.

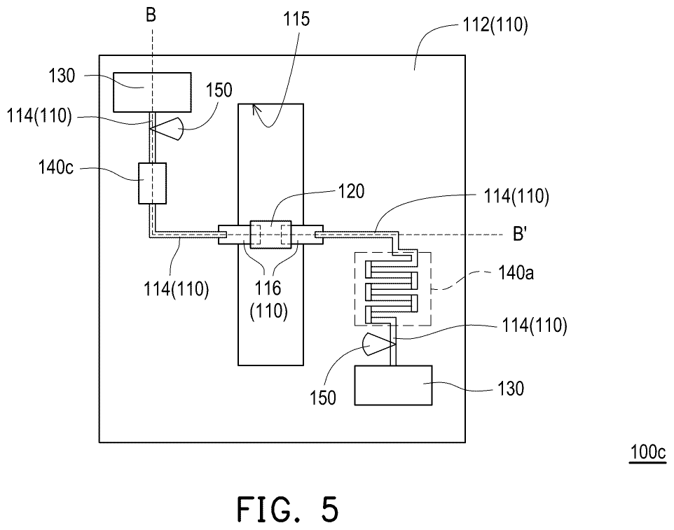

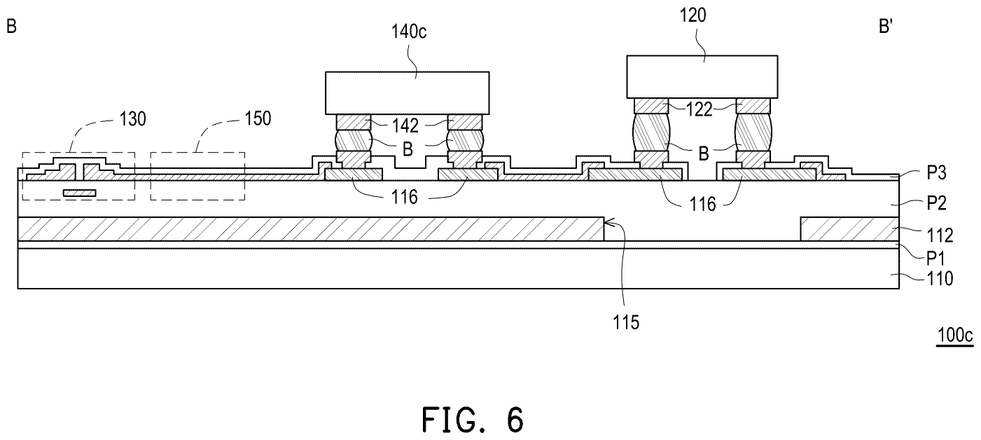

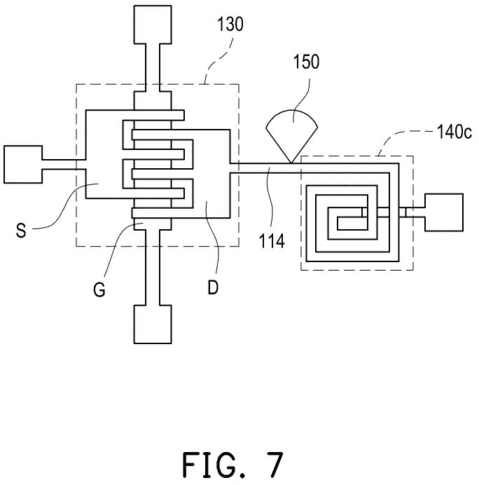

FIG. 5 is a schematic view of an electronic device according to another embodiment of the present disclosure. FIG. 6 is a schematic cross-sectional view along line B-B′ of FIG. 5. FIG. 7 is a partial enlarged schematic view of the electronic device of FIG. 5. For convenience of explanation, some components, such as protective layers, are omitted from FIG. 5 and FIG. 7. Please refer to FIG. 2 and FIG. 5 at the same time. The electronic device 100c is similar to the electronic device 100b of FIG. 3, and the difference between the two is that, in this embodiment, the structural design of the RF choke 140c of the electronic device 100c is different from the structural design of the RF choke 140a.

In detail, please refer to FIG. 5, FIG. 6 and FIG. 7 at the same time. In this embodiment, the RF choke 140c is embodied as a DC signal controller with an RF choke circuit, wherein the pad 142 of the RF choke 140c is electrically and physically connected to the signal trace 114 of the substrate 110 through surface-mount technology. In other words, the RF choke 140a and the RF choke 140c may have different structural types, and any structural design that is able to isolate RF electromagnetic signals may be adopted for implementation. Here, the bypass capacitor 150 and the signal trace 114 are integrated together. That is to say, the conductive lines and/or conductive patterns of part of the bypass capacitor 150 and the signal trace 114 belong to the same film layer. As shown in FIG. 6, the distance between the RF modulation element 120 and the substrate 110 may be slightly higher than the distance between the control circuit 130 and the substrate 110, but is not limited thereto. In addition, as shown in FIG. 7, the source S and drain D of the control circuit 130 may also be in the same film layer as the signal trace 114, but are not limited thereto.

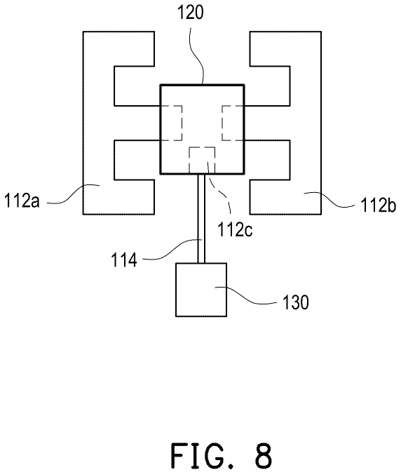

FIG. 8 to FIG. 10 are schematic views of various electronic devices according to various embodiments of the present disclosure. For convenience of explanation, some components, such as the substrate, RF choke, etc., are omitted from FIG. 8 to FIG. 10. In the embodiments of FIG. 8 to FIG. 10, the electronic device may be, for example, a phased array antenna, but is not limited thereto.

Please refer to FIG. 8. In this embodiment, the first part 112a and the second part 112b of the metal layer are opposite to each other and are in an E-shaped pattern in mirror disposition, for example. The third part 112c of the metal layer is disposed between the first part 112a and the second part 112b. The pattern of the third part 112c is different from the patterns of the first part 112a and the second part 112b. The signal trace 114 is connected to the third part 112c of the metal layer and the control circuit 130, and the RF modulation element 120 is connected to the first part 112a, the second part 112b and the third part 112c of the metal layer.

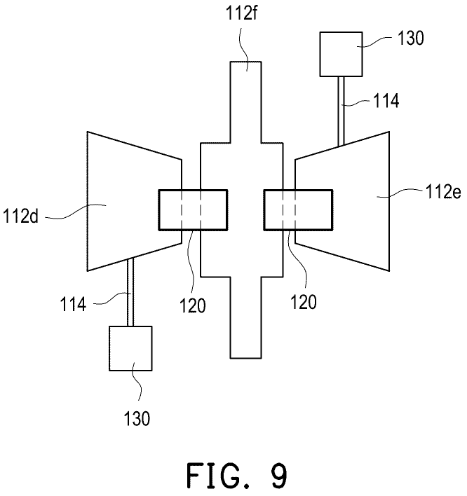

Please refer to FIG. 9. In this embodiment, the first part 112d and the second part 112e of the metal layer are opposite to each other and are in a trapezoidal pattern in mirror disposition, for example. The third part 112f of the metal layer is disposed between the first part 112a and the second part 112b. The pattern of the third part 112f is different from the patterns of the first part 112d and the second part 112e. The signal trace 114 is connected to the first part 112d of the metal layer and the control circuit 130, and the other signal trace 114 is connected to the second part 112e of the metal layer and another control circuit 130, wherein the two control circuits 130 are arranged diagonally. The RF modulation element 120 is connected to the first part 112d and the third part 112f of the metal layer, and the other RF modulation element 120 is connected to the second part 112e and the third part 112f of the metal layer.

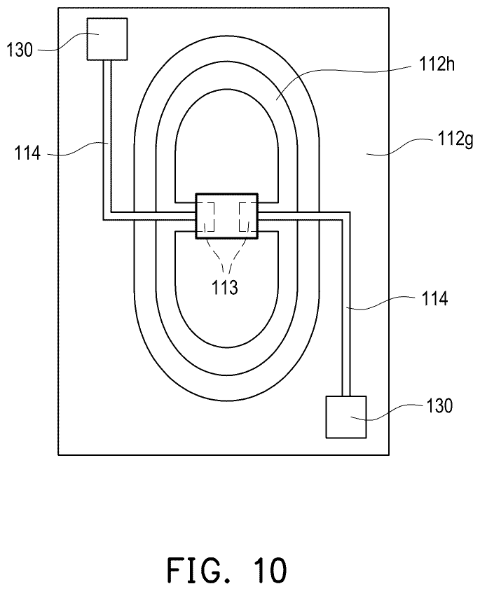

Please refer to FIG. 10. In this embodiment, the first part 112g of the metal layer surrounds the second part 112h of the metal layer, and the first part 112g and the second part 112h are spaced apart. The RF modulation element 120 is connected to the two protrusions 113 of the second part 112h of the metal layer, and the control circuit 130 is disposed above the first part 112g of the metal layer. The two control circuits 130 are arranged diagonally, and the signal trace 114 is connected to the RF modulation element 120 and the control circuit 130.

To sum up, in the electronic device of the present disclosure, since the orthographic projections of the RF modulation element, the control circuit and the RF choke on the substrate do not overlap each other, that is, the RF choke is not integrated into the RF modulation element, compared with the related art in which the circuit design for isolating RF electromagnetic signals is integrated in the RF modulation element, the RF modulation element of the present disclosure may have a smaller size, thereby effectively reducing the cost of the electronic device of the present disclosure.

Finally, it should be noted that the above embodiments are only used to illustrate the technical solutions of the disclosure and are not intended to limit it. Although the disclosure has been described in detail with reference to the above embodiments, persons of ordinary skill in the art should understand that they may still modify the technical solutions described in the above embodiments, or replace some or all of the technical features therein with equivalents, and that modifications or replacements of corresponding technical solutions do not substantially deviate from the scope of the technical solutions of the embodiments of the disclosure.

What is claimed is:

1. An electronic device, comprising:
a substrate;
a radio frequency (RF) modulation element disposed on the substrate;
a control circuit disposed on the substrate; and
a radio frequency (RF) choke disposed on the substrate, and electrically coupled between the RF modulation element and the control circuit, wherein orthographic projections of the RF modulation element, the control circuit and the RF choke on the substrate do not overlap each other.

2. The electronic device according to claim 1, wherein the substrate comprises a metal layer and an opening penetrating the metal layer, wherein the orthographic projection of the RF modulation element on the substrate overlaps the opening, and the orthographic projections of the control circuit and the RF choke on the substrate overlap the metal layer.

3. The electronic device according to claim 2, further comprising:
a reflective structural layer, wherein the metal layer and the reflective structural layer are respectively located on opposite side surfaces of the substrate.

4. The electronic device according to claim 2, wherein a first part and a second part of the metal layer are opposite to each other and are in an E-shaped pattern in mirror disposition, and a third part of the metal layer is disposed between the first part and the second part.

5. The electronic device according to claim 2, wherein a first part and a second part of the metal layer are opposite to each other and are in a trapezoidal pattern in mirror disposition, and a third part of the metal layer is disposed between the first part and the second part.

6. The electronic device according to claim 2, wherein a first part of the metal layer surrounds a second part of the metal layer, and the first part and the second part are spaced apart.

7. The electronic device according to claim 2, wherein a material of the metal layer comprises copper, aluminum, silver, gold, indium tin oxide (ITO), metal alloys, or a combination of the above materials.

8. The electronic device according to claim 1, wherein the substrate comprises a signal trace, wherein the signal trace is connected between the RF modulation element and the RF choke and connected between the RF choke and the control circuit.

9. The electronic device according to claim 8, further comprising:
a bypass capacitor electrically coupled between the control circuit and the RF choke.

10. The electronic device according to claim 9, wherein the bypass capacitor, the RF choke and the signal trace are integrated together.

11. The electronic device according to claim 9, wherein the bypass capacitor and the signal trace are integrated together.

12. The electronic device according to claim 11, wherein the RF choke is connected to the signal trace through a surface-mount technology.

13. The electronic device according to claim 8, wherein a source and a drain of the control circuit and the signal trace belong to a same film layer.

14. The electronic device according to claim 1, wherein a distance between the RF modulation element and the substrate is slightly higher than a distance between the control circuit and the substrate.

15. The electronic device according to claim 1, wherein the RF modulation element is connected to a conductive pattern of the substrate through a solder.

16. The electronic device according to claim 1, wherein the RF modulation element comprises a varactor.

17. The electronic device according to claim 1, wherein the control circuit comprises a transistor or an integrated circuit.

18. The electronic device according to claim 1, wherein a material of the substrate comprises glass, quartz, silicon wafer, sapphire, a Group III-V semiconductor material, ceramic, polycarbonate (PC), polyimide (PI), polyethylene terephthalate (PET), or a combination of the foregoing.

19. The electronic device according to claim 1, wherein the substrate comprises a printed circuit board.

20. The electronic device according to claim 1, wherein the electronic device is a diode-tuned RF signal modulation array.
